(19) United States
(12) Patent Application Publication
(10) Pub. No.: US 2008/0066953 A1
(43) Pub. Date: Mar. 20, 2008

(54) Circuit board assembly and manufacturing method thereof, electronic part assembly and manufacturing method thereof, and electronic device

(75) Inventor: Ryo Kanai, Kawasaki (JP)

Correspondence Address: STAAS & HALSEY LLP, SUITE 700, 1201 NEW YORK AVENUE, N.W., WASHINGTON, DC, 20005, US

(73) Assignee: FUJITSU LIMITED, KAWASAKI (JP)

(21) Appl. No.: 11/878,599

(22) Filed: Jul. 25, 2007

(30) Foreign Application Priority Data
Sep. 19, 2006 (JP) 2006-252937

(51) Int. Cl. H05K 1/16; H05K 3/30

(52) U.S. Cl. 174/260; 29/832; 174/255; 29/830

(57) ABSTRACT

A circuit board assembly includes a circuit board on which an electronic part is mounted. A flexible circuit board is attached to a bottom surface of the circuit board. The flexible circuit board has at least one extending part that extends from a side of the bottom surface of the circuit board so as to cover a side surface of the circuit board.

### BACKGROUND OF THE INVENTION

1. Field of the Invention

The present invention relates to electronic parts and, more particularly, to a circuit board on which a circuit radiating an undesired electromagnetic wave is formed, and an electronic part assembly in which electronic parts are mounted on such a circuit board.

2. Description of the Related Art

Electronic parts used as parts of electronic devices such as a computer or the like use signals having a high frequency in many cases, and an undesired electromagnetic wave may be generated in an electric circuit using such an electronic part. Since such an electronic circuit is formed on or in a circuit board, such an undesired electromagnetic wave is radiated from the circuit board, which may give a bad influence to surrounding electronic parts. In order to shield the electromagnetic wave from an electronic part or an electronic circuit, it is general to surround the electronic part or the electronic circuit by an electronically conductive material.

For example, as a shield structure for electromagnetically shielding an electronic part on a circuit board or a substrate, there is suggested a structure for shielding an electronic part on a circuit board by covering above the electronic part by a flexible circuit board. (for example, refer to Patent Document 1).

Patent Document 1: Japanese Laid-Open Patent Application No. 2005-303067

As a circuit board or a substrate for mounting electronic parts thereon, a multilayer circuit board in which conductive layers are laminated in a multi layer structure is used in many cases so as to form a complex circuit. Since the multilayer circuit board has a structure in which many electrically conductive layers are stacked, it has a relatively large thickness. When constituting an electronic circuit by mounting electronic parts on such a multilayer circuit board, a shield effect can be obtained by using a part of the electrically conductive layers as a power supply layer or a ground layer. In this case, an electromagnetic wave is not radiated in a direction perpendicular to a laminating direction of the multilayer circuit board.

However, side surfaces or end surfaces of a multilayer circuit board are in a state where side or end surfaces of the conductive layers serving as signal lines are exposed, and there is nothing shielding electromagnetic waves, and, thus, there may be a case where an undesired electromagnetic wave is radiated from the side or end surfaces of the multilayer circuit board. Especially in recent years, electronic parts have been made to handle signals having higher frequencies, and a number of stacked layers is increased which increases a thickness thereof, and, thus, the electromagnetic waves radiated from the side or end surfaces of the multilayer circuit board has become problematic.

### SUMMARY OF THE INVENTION

It is a general object of the present invention to provide an improved and useful circuit board assembly in which the above-mentioned problems are eliminate.

A more specific object of the present invention is to provide a circuit board assembly, an electronic part assembly and an electronic device that have a structure for shielding an electromagnetic wave radiated from side or end surfaces of a circuit board.

In order to achieve the above-mentioned objects, there is provided according to one aspect of the present invention a circuit board assembly on which an electronic part is mounted, comprising: a circuit board on which the electronic part is mounted; and a flexible circuit board attached to a bottom surface of the circuit board, wherein the flexible circuit board has at least one extending part that extends from a side of the bottom surface of the circuit board so as to cover a side surface of the circuit board.

In the circuit board assembly according to the present invention, an end portion of the extending part of the flexible circuit board may be connected to a surface opposite to the bottom surface of the circuit board. The circuit board may be a multilayer circuit board having rigidity. The extending part of the flexible circuit board may extend from each side of the bottom surface of the circuit board and may be bent so as to extend along the side surface of the circuit board. The flexible circuit board may include a base, an electrically conductive layer formed on an entire surface of the base and a cover layer provided to cover the electrically conductive layer, and wherein the base of the flexible circuit board may be joined to the bottom surface of the circuit board. An opening penetrating through the base may be provided in the end portion of the extending part of the flexible circuit board, and the end portion of the extending part of the flexible circuit board may be joined to a wiring pattern on a surface opposite to the bottom surface of the circuit board. The wiring pattern on the surface opposite to the bottom surface may be a wiring part to be at a ground potential. Each extending part of the flexible circuit board may have a fold-in part to be bent along a corner between the side surface and another side surface adjacent to the side surface so that the fold-in part is arranged between the another side surface and another extending part covering the another side surface.

Additionally, there is provided according to another aspect of the present invention an electronic device comprising: at least one electronic part; and a circuit board assembly on which the electronic part is mounted, wherein the circuit board assembly includes: a circuit board on which the electronic part is mounted; and a flexible circuit board attached to a bottom surface of the circuit board, wherein the flexible circuit board has at least one extending part that extends from a side of the bottom surface of the circuit board so as to cover a side surface of the circuit board.

Further, there is provided according to another aspect of the present invention a manufacturing method of a circuit board assembly, comprising: attaching a flexible circuit board on a bottom surface of a circuit board on which at least one electronic part is mounted; bending extending parts of the flexible circuit board extending from the bottom surface of the circuit board, the extending parts being arranged to extend along side surfaces of the circuit board so as to wrap the circuit board by the flexible circuit board; and connecting the extending parts of the flexible circuit board to a surface opposite to the bottom surface of the circuit board.

Additionally, there is provided according further aspect of the present invention an electronic part assembly comprising a circuit board assembly and at least one electronic part mounted on the circuit board assembly, wherein the circuit board assembly includes: a circuit board on which the electronic part is mounted; and a flexible circuit board attached to a bottom surface of the circuit board, wherein the flexible circuit has at least one extending part that extends from a side of the bottom surface of the circuit board so as to cover a side surface of the circuit board.

In the electronic part assembly according to the present invention, an end portion of the extending part of the flexible circuit board may be connected to a surface opposite to the bottom surface of the circuit board. The circuit board may be a multilayer circuit board having rigidity. The extending part of the flexible circuit board may extend from each side of the bottom surface of the circuit board and is bent so as to extend along the side surface of the circuit board. The flexible circuit board may include a base, an electrically conductive layer formed on an entire surface of the base and a cover layer provided to cover the electrically conductive layer, and wherein the base of the flexible circuit board is joined to the bottom surface of the circuit board. An opening penetrating through the base may be provided in the end portion of the extending part of the flexible circuit board, and the end portion of the extending part of the flexible circuit board may be joined to a wiring pattern on a surface opposite to the bottom surface of the circuit board. The wiring pattern on the surface opposite to the bottom surface may be a wiring part to be at a ground potential. Each extending part of the flexible circuit board may have a fold-in part to be bent along a corner between the side surface and another side surface adjacent to the side surface so that the fold-in part is arranged between the another side surface and another extending part covering the another side surface.

Additionally, there is provided according to another aspect of the present invention a manufacturing method of an electronic part assembly comprising a circuit board assembly and at least one electronic part mounted on the circuit board, the manufacturing method comprising: attaching a flexible circuit board on a bottom surface of the circuit board on which the electronic part is mounted; bending extending parts of the flexible circuit board extending from the bottom surface of the circuit board, the extending parts being arranged to extend along side surfaces of the circuit board so as to wrap the circuit board by the flexible circuit board; and connecting the extending parts of the flexible circuit board to a surface opposite to the bottom surface of the circuit board.

The above-mentioned manufacturing method may further comprise a step of mounting the electronic part on the surface opposite to the bottom surface of the circuit board.

According to the above-mentioned invention, by covering the side surfaces of the circuit board by the extending parts of the flexible circuit board, the side surfaces of the circuit board can be electromagnetically shielded by the conductive layer of the flexible circuit board.

Other objects, features and advantages of the present invention will become more apparent from the following detailed description when read in conjunction with the accompanying drawings.

### BRIEF DESCRIPTION OF DRAWINGS

FIG. 1 is a cross-sectional view showing a state in a middle of a manufacturing process of an electronic part assembly according to a first embodiment of the present invention;

FIG. 2 is a cross-sectional view showing a state a state where the electronic part assembly shown in FIG. 1 is completed;

FIG. 3 is an illustration showing a structure to cover four side-surfaces of a multilayer circuit board by a flexible circuit board; and

FIG. 4 is a plan view of a flexible circuit board that can cover corners of the multilayer circuit board.

### DETAILED DESCRIPTION OF THE PREFERRED EMBODIMENTS

A description will be given, with reference to an electronic part assembly according to an embodiment of the present invention.

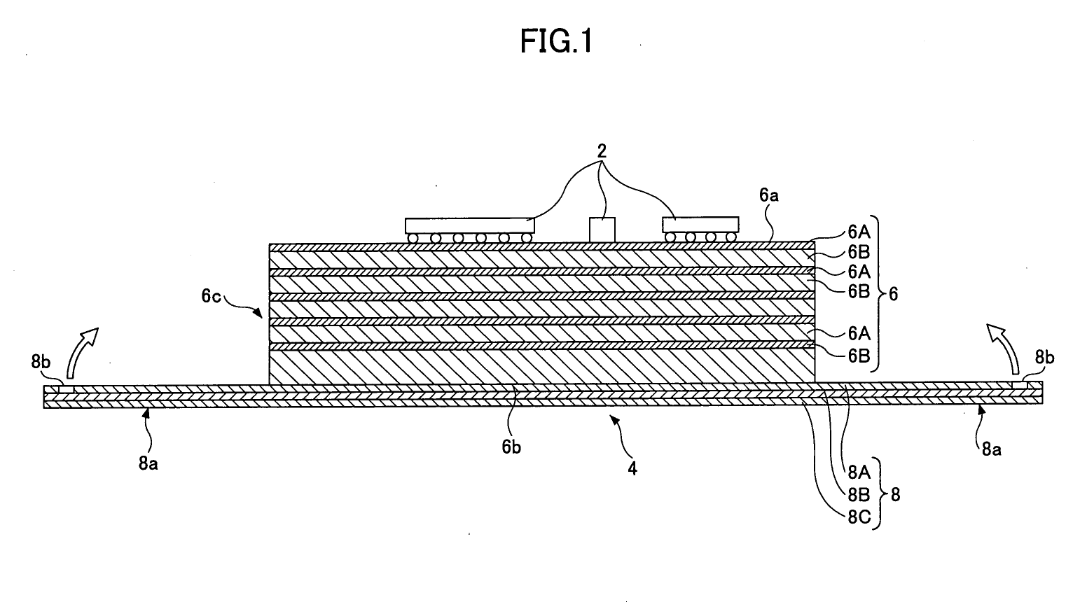

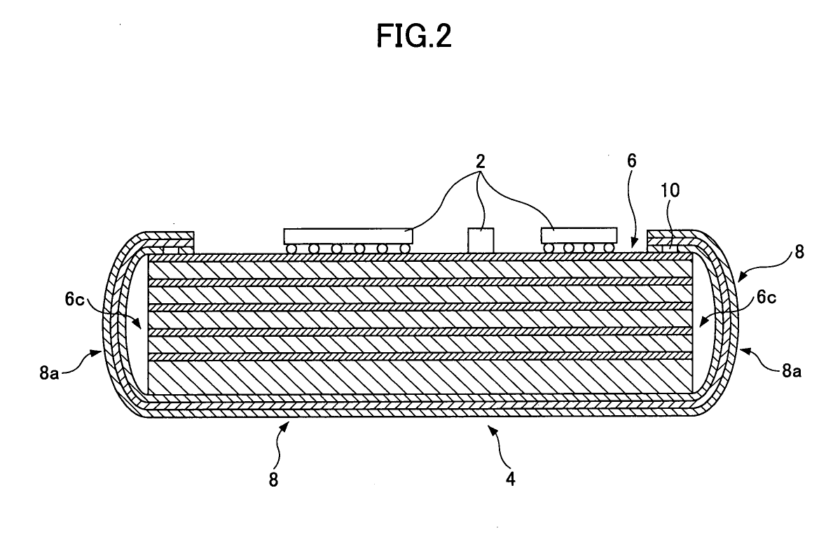

FIG. 1 is a cross-sectional view showing a state in a middle of a manufacturing of an electronic part assembly according to an embodiment of the present invention, and FIG. 2 is a cross-sectional view showing a state where the electronic part assembly shown in FIG. 1 is completed.

The electronic part assembly according to the embodiment of the present invention has a circuit board assembly 4 for mounting electronic parts 2. The electronic parts 2 are the semiconductor devices and peripheral elements, and form an electronic circuit by being mounted on the circuit board assembly 4.

The circuit board assembly 4 comprises a multilayer board 6 and a flexible circuit board 8 attached to the multilayer board 6.

Although the multilayer board 6 is a so-called rigid substrate that is formed by electrically conductive layers 6A and insulating layers 6B being stacked in multiple layers in the present embodiment, the multilayer board 6 may be other substrates. The electrically conductive layer 6A is formed by an electrically conductive metal such as, for example, copper. On the other hand, the insulating layer 6B is formed by an insulating material such as glass-epoxy. The electronic parts 2 are mounted on the multilayer board 6.

The flexible circuit board 8 comprises a base 8A having flexibility, an electrically conductive layer 8B formed on the base 8A and a cover layer 8C provided to cover the electrically conductive layer 8B. The base 8A is, for example, a film having flexibility such as a polyimide film, and can be bent easily. The electrically conductive layer 8B is formed by an electrically conductive metal such as, for example, copper. The cover layer 8C is, for example, a thin film of polyimide formed to cover and protect the electrically conductive layer 8B.

The flexible circuit board 8 is attached to a bottom surface 6b of the multilayer board 6 by joining the base 8A to the bottom surface 6b of the multilayer board 6 by an adhesive or the like. The flexible circuit board 8 is larger than the multilayer board 6, and is attached the bottom surface 6b of the multilayer board 6 so as to extend from a side surface (or an end surface) 6c of the multilayer board 6. It should be noted that, when forming the multilayer board 6, the flexible circuit board 8 may be attached to the multilayer board 6 by attaching the flexible circuit board 8 to the bottom surface 6b when the insulating layer 6B providing the bottom surface 6b is in a pre-preg state.

After mounting the electronic parts 2 to the circuit board assembly 4 of the above-mentioned structure, extending parts 8a of the flexile circuit board 8 extending from the bottom surface 6b of the multilayer board 6 are bent in directions indicated by arrows of FIG. 1 so as connect end portions of the extending parts 8a to a mounting surface 6a of the multilayer board 6. Thereby, the side surfaces 6c of the multilayer board 6 are covered by the extending parts 8a of the flexible circuit board 8b, and the multilayer board 6 is in a state where it is wrapped by the flexible circuit board 8.

Here, it is preferable to bend the flexible circuit board 8 so as to extend along a vicinity of the side surfaces 6c of the multilayer board 6 by making the flexible circuit board 8 to be thin and have large flexibility. Although the thickness of the flexible circuit board 8 is indicated large in the example shown in FIG. 2 for the sake of convenience, it is a thinner film than that shown practically and can be bent easily with a small bending radius.

In the end portions of the extending parts 8a of the flexible board 8, the base 8A is partially removed and openings 8b are formed in portions to be connected to the mounting surface 6a of the multilayer board 6 so that the electrically conductive layer 8B is exposed in the openings 8b. The electrically conductive layer 8B of the flexible circuit board 8 is joined to the mounting surface 6a of the multilayer board 6 by filling an electrically conductive joining material 10 such as solder, electrically conductive resin, or the like in the openings 8b. It is preferable that the portions joined by the joining material 10 on the mounting surface are wiring portions to be set at a ground potential. However, it is not limited to such a connection method, the base 8A at the end portions of the flexible circuit board 8 may be fixed to the mounting surface 6a of the multilayer board 6 by an adhesive and the electrically conductive layer 8B of the flexible circuit board 8 may be electrically connected to a ground potential part.

Moreover, although the flexible circuit board 8 is bent to cover the side surfaces 6c after mounting the electronic parts 2 to the circuit board assembly 4 in the present embodiment, the flexible circuit board 8 may be bent to cover the side surfaces 6c with the circuit board assembly 4 alone before mounting the electronic parts 2 to the circuit board assembly 4. In such a case, the circuit board assembly 4 functions as a single substrate of which side surfaces are electromagnetically shielded.

In the electronic part assembly of the above-mentioned structure shown in FIG. 2, the side surfaces 6c or the end surfaces of the multilayer board 6 are covered by the electrically conductive layer 8B of the flexible circuit board 8, and, thus, the side surfaces 6c of the multilayer board 6 can be electromagnetically shielded by setting the electrically conductive layer 8B of the flexible circuit board 8 at a ground potential. Thereby, if an undesired electromagnetic wave is radiated from the side surfaces 6c of the multilayer board 6, it is shielded by the conductive layer 8B of the flexible circuit board 8, which can provide the electronic part assembly that does not radiate an unnecessary electromagnetic wave.

Although it is shown in FIG. 2 that two side surfaces 6c are covered by the flexible circuit board 8, it is preferable to cover all four side-surfaces by the flexible circuit board 8 since the multilayer board 6 normally has side surfaces 6c in four directions.

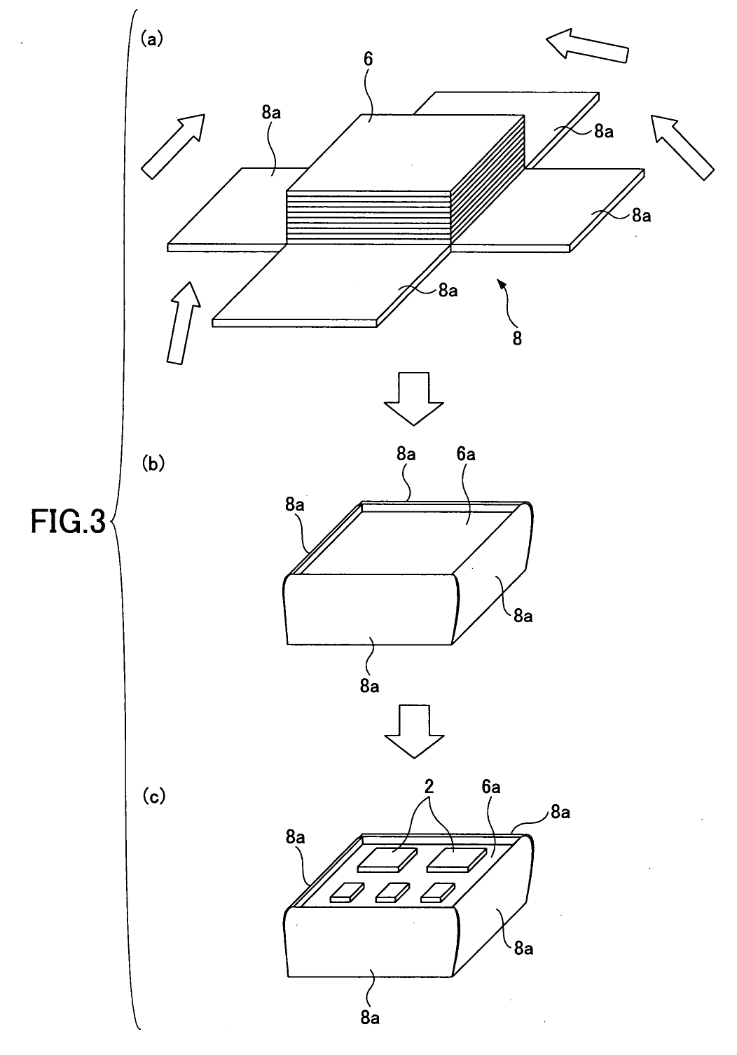

In FIG. 3, the flexible circuit board 8 attached to the bottom surface 6b of the multilayer board 6 has the extending parts 8a which extend from the respective sides of the bottom surface 6b of the multilayer board 6. Therefore, all of the four side-surfaces 6c of the multilayer board 6 can be covered by the flexible circuit board 8 by bending the extending parts 8a, which extend in the four directions, inward as indicated by arrows in FIG. 3-(a). Then, by connecting each of the end portions of the extending parts 8b to the mounting surface 6a of the multilayer board 6, the circuit board assembly such as shown in FIG. 3-(b) is completed. Thereafter, as shown in FIG. 3-(c), the electronic part assembly is completed by mounting the electronic parts to the mounting surface 6a of the circuit board assembly. As mentioned above, the process of mounting the electronic parts may be performed before attaching the flexible circuit board 8 to the multilayer board 6. Alternatively, it may be performed after the flexible circuit board 8 is attached to the multilayer board 6 and before wrapping the multilayer board 6 by the flexible circuit board 8.

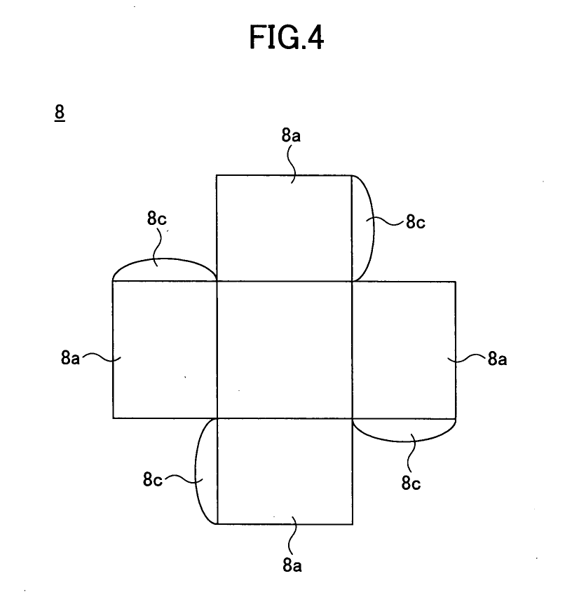

It should be noted that in the example shown in FIG. 3, each corner where the adjacent side surfaces 6c of the multilayer board 6 intersect may not be covered completely by the flexible circuit board 8. Thus, as shown in FIG. 4, a fold-in part Bc may be provided on one side of each extending part 8a of the flexible circuit board 8.

Each fold-in part 8c is bent, after each extending part 8a is bent to extend along the corresponding side surface 6c, to extend along the side surface 6c adjacent to the side surface 6c concerned. Accordingly, when the adjacent extending part 8a is bent, the fold-in part 8c concerned is covered by the extending part 8a. By performing such folding sequentially, the circuit board assembly in which the corners of the side surfaces 6c are also be covered by the flexible circuit board 8c. Thereby, the circuit board assembly, the electronic part assembly and the electronic device in which radiation of an electromagnetic wave is reduced can be realized.

It should be noted that although the electronic parts 2 are mounted to the mounting surface 6a of the multilayer board 6 in the above-mentioned embodiment, electronic parts may be mounted also on the bottom surface 6b opposite to the mounting surface 6a. In such a case, the flexible circuit board 8 is not in a shape to cover the entire bottom surface 6b, and is provided with openings so that it does not cover portions of the bottom surface 6b where the electronic parts are mounted. Or, it is not necessary to make the flexible circuit board 8 to be a single sheet. For example, the flexible circuit board 8 may be made of four sheets so that each sheet covers each side surface of the multilayer board 6.

The present invention is not limited to the specifically disclosed embodiments, and variations and modifications may be made without departing from the scope of the present invention.

The present application is based on Japanese priority application No. 2006-252937 filed Sep. 19, 2006, the entire contents of which are hereby incorporated herein by reference.

What is claimed is:

1. A circuit board assembly on which an electronic part is mounted, comprising:
a circuit board on which the electronic part is mounted; and
a flexible circuit board attached to a bottom surface of the circuit board,
wherein the flexible circuit board has at least one extending part that extends from a side of the bottom surface of said circuit board so as to cover a side surface of said circuit board.

2. The circuit board assembly as claimed in claim 1, wherein an end portion of said extending part of said flexible circuit board is connected to a surface opposite to said bottom surface of said circuit board.

3. The circuit board assembly as claimed in claim 1, wherein said circuit board is a multilayer circuit board having rigidity.

4. The circuit board assembly as claimed in claim 1, wherein said extending part of said flexible circuit board extends from each side of said bottom surface of said circuit board and is bent so as to extend along said side surface of said circuit board.

5. The circuit board assembly as claimed in claim 1, wherein said flexible circuit board includes a base, an electrically conductive layer formed on an entire surface of the base and a cover layer provided to cover the electrically conductive layer, and wherein said base of said flexible circuit board is joined to said bottom surface of said circuit board.

6. The circuit board assembly as claimed in claim 5, wherein an opening penetrating through said base is provided in said end portion of said extending part of said flexible circuit board, and said end portion of said extending part of said flexible circuit board is joined to a wiring pattern on a surface opposite to said bottom surface of said circuit board.

7. The circuit board assembly as claimed in claim 5, wherein said wiring pattern on the surface opposite to said bottom surface is a wiring part to be at a ground potential.

8. The circuit board assembly as claimed in claim 1, wherein each extending part of said flexible circuit board has a fold-in part to be bent along a corner between said side surface and another side surface adjacent to said side surface so that the fold-in part is arranged between said another side surface and another extending part covering said another side surface.

9. An electronic device comprising:
at least one electronic part; and
a circuit board assembly on which the electronic part is mounted,
wherein the circuit board assembly includes:
a circuit board on which the electronic part is mounted; and
a flexible circuit board attached to a bottom surface of the circuit board,
wherein the flexible circuit board has at least one extending part that extends from a side of the bottom surface of said circuit board so as to cover a side surface of said circuit board.

10. A manufacturing method of a circuit board assembly, comprising:
attaching a flexible circuit board on a bottom surface of a circuit board on which at least one electronic part is mounted;
bending extending parts of the flexible circuit board extending from said bottom surface of said circuit board, the extending parts being arranged to extend along side surfaces of said circuit board so as to wrap said circuit board by said flexible circuit board; and
connecting said extending parts of said flexible circuit board to a surface opposite to said bottom surface of said circuit board.

11. An electronic part assembly comprising a circuit board assembly and at least one electronic part mounted on the circuit board assembly,
wherein said circuit board assembly includes:
a circuit board on which the electronic part is mounted; and
a flexible circuit board attached to a bottom surface of the circuit board,
wherein the flexible circuit has at least one extending part that extends from a side of the bottom surface of said circuit board so as to cover a side surface of said circuit board.

12. The electronic part assembly as claimed in claim 11, wherein an end portion of said extending part of said flexible circuit board is connected to a surface opposite to said bottom surface of said circuit board.

13. The electronic part assembly as claimed in claim 11, wherein said circuit board is a multilayer circuit board having rigidity.

14. The electronic part assembly as claimed in claim 11, wherein said extending part of said flexible circuit board extends from each side of said bottom surface of said circuit board and is bent so as to extend along said side surface of said circuit board.

15. The electronic part assembly as claimed in claim 11, wherein said flexible circuit board includes a base, an electrically conductive layer formed on an entire surface of the base and a cover layer provided to cover the electrically conductive layer, and wherein said base of said flexible circuit board is joined to said bottom surface of said circuit board.

16. The electronic part assembly as claimed in claim 15, wherein an opening penetrating through said base is provided in said end portion of said extending part of said flexible circuit board, and said end portion of said extending part of said flexible circuit board is joined to a wiring pattern on a surface opposite to said bottom surface of said circuit board.

17. The electronic part assembly as claimed in claim 15, wherein said wiring pattern on the surface opposite to said bottom surface is a wiring part to be at a ground potential.

18. The electronic part assembly as claimed in claim 11, wherein each extending part of said flexible circuit board has a fold-in part to be bent along a corner between said side surface and another side surface adjacent to said side surface so that the fold-in part is arranged between said another side surface and another extending part covering said another side surface.

19. A manufacturing method of an electronic part assembly comprising a circuit board assembly and at least one electronic part mounted on the circuit board, the manufacturing method comprising:
attaching a flexible circuit board on a bottom surface of the circuit board on which the electronic part is mounted;
bending extending parts of the flexible circuit board extending from said bottom surface of said circuit board, the extending parts being arranged to extend along side surfaces of said circuit board so as to wrap said circuit board by said flexible circuit board; and
connecting said extending parts of said flexible circuit board to a surface opposite to said bottom surface of said circuit board.

20. The manufacturing method as claimed in claim 19, further comprising a step of mounting said electronic part on the surface opposite to said bottom surface of said circuit board.
